(19) United States
(12) Patent Application Publication
(10) Pub. No.: US 2012/0139565 A1
(43) Pub. Date: Jun. 7, 2012

(54) MOISTURE SENSING

(75) Inventor: Bruce P. Ambuter, Monument Beach, MA (US)

(73) Assignee: POLYGON US CORPORATION, Amesbury, MA (US)

(21) Appl. No.: 12/960,040

(22) Filed: Dec. 3, 2010

(51) Int. Cl. G01R 27/08

(52) U.S. Cl. 324/694

(57) ABSTRACT

Measuring moisture content of a material under test. First and second sense voltages across a sense resistor are detected in response to application of respective first and second supply voltages across the sense resistor and the material under test. The material under test is electrically coupled to the sense resistor. A net sense voltage is determined by determining a difference between the second and first sense voltages. A resistance of the material under test is determined based on the net sense voltage, a predetermined resistance of the sense resistor, and the second supply voltage. A moisture content of the material under test is determined based on the resistance of the material under test.

### FIELD

The present disclosure relates to determining the moisture content of a material under test, and, more particularly, relates to determining the moisture content of the material under test based on a resistance of the material under test.

### BACKGROUND

In the field of this disclosure, it is common to determine moisture content of wood by direct measurement of the resistivity of the wood (or other material) under test, and comparing the measured resistivity with a correlation between various resistance values and known moisture content values for the wood. In one example, the resistivity of the wood under test is measured by driving two electrodes into the wood, applying a high voltage to one electrode, and attaching a fixed known resistance to the other electrode. The resistivity of the wood may be determined by measuring the voltage drop across the known series resistor, and using Ohm's law to calculate the resistivity of the wood for the applied voltage.

Some conventional measurement techniques use an analog-to-digital converter (ADC) to measure an analog voltage drop across the known resistor and provide a digital equivalent of the analog voltage to a microprocessor which records and controls the measurement process. Such a technique typically works over a limited range of resistivity values of the material under test. A wider range of resistivity values is ordinarily accommodated by using several known resistors to cover different ranges of resistivity values of the material under test, one resistor being selected using a multiplexer.

### SUMMARY

The inventor has observed that the accuracy of such conventional measurement techniques is typically limited by the amount of available voltage that is applied to the electrode. The inventor has also observed that the accuracy of such conventional measurement techniques is affected by measurement errors, such as for example, measurement errors due to increased Johnson resistance noise, bias currents, and mismatches in measurement circuit electronics.

In one example embodiment, the foregoing situation is addressed through the provision an adjustable power supply that is controlled to provide a specified supply voltage to a series circuit that includes the material under test and a single sense resistor, and a controller that controls the supply voltage to accommodate a range of resistivity values of the material under test.

Thus, in an example embodiment described herein, moisture content of a material under test is measured by detecting first and second sense voltages across a sense resistor, in response to application of respective first and second supply voltages across the sense resistor and the material under test. The material under test is electrically coupled to the sense resistor. A net sense voltage is determined by determining a difference between the second and first sense voltages. A resistance of the material under test is determined based on the net sense voltage, a predetermined resistance of the sense resistor, and the second supply voltage. A moisture content of the material under test is determined based in part on the resistance of the material under test.

By virtue of using a sense resistor (in one example, it is a single sense resistor), the foregoing arrangement is more accurate as compared to conventional measurement techniques that select one of a plurality of resistors using a multiplexor, since errors associated with a multiplexor are not introduced into the measurements.

Also, by using the net sense voltage to calculate the resistance of the material under test, the effects of input bias currents and other parasitic parameters can be reduced.

In an example embodiment described herein, the controller detects each of the first sense voltage and the second sense voltage by taking a predetermined number of voltage measurements of the sense resistor at predetermined intervals, and averaging the voltage measurements.

By virtue of averaging multiple voltage measurements, a signal-to-noise ratio can be improved.

In an example embodiment described herein, the determining of the net sense voltage is performed in response to a detection that the second sense voltage exceeds a predetermined percentage of a full-scale voltage measurement of a controller that controls an adjustable power supply to increase the second supply voltage until the second sense voltage exceeds the predetermined percentage of the full-scale voltage measurement.

In an example embodiment described herein, the predetermined percentage of the full-scale voltage measurement of the controller is fifty percent (50%), and the controller controls the power supply to double the second supply voltage until the second sense voltage is greater than half of the full-scale voltage measurement. The resistance of the material under test is determined using Ohm's law.

In another example embodiment described herein, the moisture content is output to a display device that displays the moisture content to a user. In another example embodiment, the moisture content is output to a dryer controller that controls a dryer to dry/stop drying the material under test, based on the moisture content. In another example embodiment, the moisture content is output to a remote device via a network, and the remote device performs an action based on the received moisture content.

In a further example embodiment described herein, the adjustable power supply is an adjustable DC-DC converter. The controller includes an analog-to-digital-converter (ADC), a processor, and a voltage adjusting potentiometer. The ADC monitors the voltage across the sense resistor and the processor reads an output of the ADC to detect the first sense voltage and the second sense voltage. The processor uses the voltage adjusting potentiometer to control the adjustable power supply. The ADC is a 24-bit delta-sigma ADC that includes a buffer amplifier.

This brief summary has been provided so that the nature of this disclosure may be understood quickly. A more complete understanding can be obtained by reference to the following detailed description and to the attached drawings.

### BRIEF DESCRIPTION OF THE DRAWINGS

FIG. 1 is a representative view of a moisture sensing device relevant to one example embodiment.

FIG. 2 is a module diagram depicting the internal architecture of one example of a controller shown in FIG. 1.

FIG. 3 is a flow diagram for explaining moisture sensing according to an example embodiment.

FIG. 4, including FIGS. 4A and 4B that are related as shown, is a schematic diagram of a moisture sensing device according to an example embodiment.

FIG. 5 is block diagram of a moisture measurement system according to an example embodiment.

FIG. 6 is a detailed block diagram depicting the internal architecture of a computer according to an example embodiment.

### DETAILED DESCRIPTION

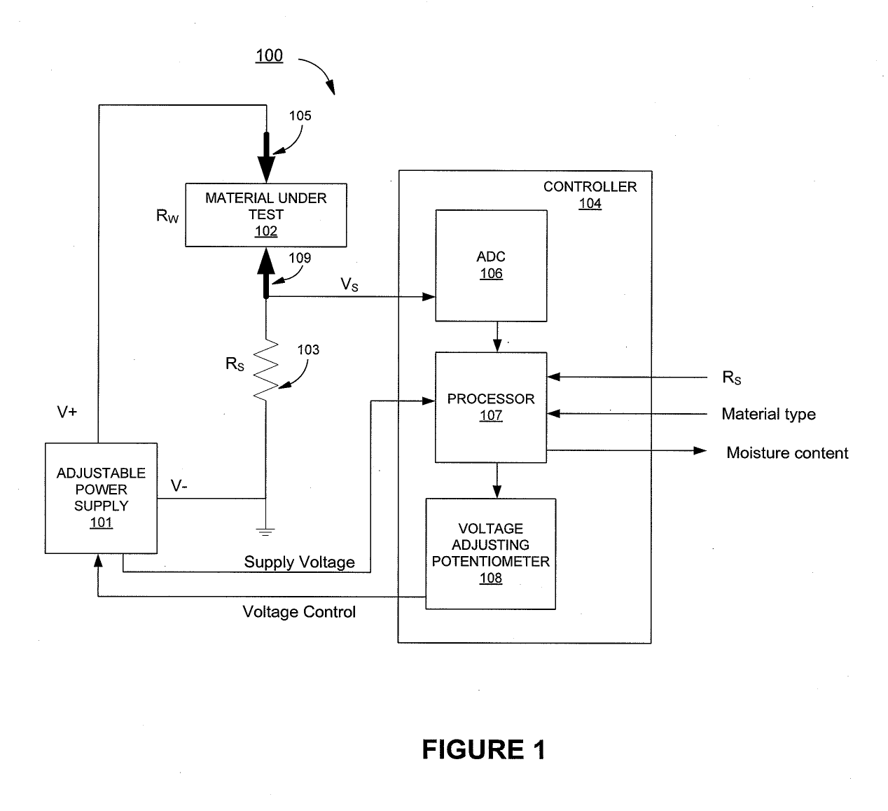

FIG. 1 is a representative view of a moisture sensing device 100 relevant to one example embodiment. Moisture sensing device 100 includes adjustable power supply 101, material under test 102, sense resistor 103, and controller 104.

Material under test 102 is a material for which the moisture content is to be determined, such as, for example, wood, drywall, or any other type of material capable of retaining moisture.

In one example embodiment, sense resistor 103 is a 1M (mega ohm) resistor, although in other embodiments, other suitable resistor values can be employed. In the example embodiment, sense resistor 103 is a resistor that is not significantly affected by external moisture, such as, for example, a metal film resistor. In the example embodiment, sense resistor 103 has a tolerance of 0.1%, however, in other embodiments, resistors having other tolerance values can be employed. In the example embodiment, sense resistor 103 has a drift characteristic of less than 100 parts per million (ppm), however, in other embodiments, resistors having other drift characteristic values can be employed.

In one example, power supply 101 is a DC-DC converter controllable by a controller, such as controller 104. In the example embodiment, power supply 101 provides a supply voltage in the range of 3V to 90V at 2 mA output current, although other values can be used in other suitable embodiments.

In the example embodiment, controller 104 is a control circuit that includes an analog-to-digital-converter (ADC) circuit 106, a processor 107, and a voltage adjusting potentiometer circuit 108. In the example embodiment, ADC 106 is a 24-bit delta-sigma ADC that includes a buffer amplifier. However, in other embodiments, the ADC can be any other suitable type of ADC.

In another example embodiment, the controller is a programmable general purpose personal computer (hereinafter “PC”) that is communicatively coupled to an ADC and a voltage adjusting potentiometer (e.g., via a USB interface, an internal bus, a network, or the like). The computer has an operating system such as Microsoft® Windows® or Apple® Mac OS® or LINUX, and is programmed so as to perform particular functions, and in effect to become a special purpose computer for measuring moisture content of the material under test. Of course, these are merely examples only, and are not intended to limit the scope of the invention.

Electrodes 105 and 109 are electrodes that are electrically coupled to material under test 102. In the example embodiment, electrodes 105 and 109 are driven at least partially into material under test 102 to form an electrical coupling therethrough.

The supply voltage provided by power supply 101 is applied to electrode 105. Electrode 109 is electrically coupled to a first electrode of sense resistor 103. The first electrode of sense resistor 103 is also electrically coupled to an input of controller 104. A second electrode of sense resistor 103 is electrically coupled to ground.

Power supply 101 receives a voltage control signal from controller 104, by which the supply voltage provided by power supply 101 is controlled. Power supply 101 provides an output to controller 104 which indicates the current value of the supply voltage.

Controller 104 receives a resistance input (R_{S}) that indicates a known resistance value of sense resistor 103. Controller 104 is communicatively coupled to a device (not shown) that receives a moisture content value output by controller 104. In an example embodiment, the device is a remote device that is communicatively coupled to the controller via a network (e.g., an intranet, the Internet, a wireless network, or the like).

In another example embodiment, the device is a display device that displays the moisture content value to a user, or another type of output device that outputs a user-perceptible indication of the moisture content. In another example embodiment, the moisture content is output to a dryer controller that controls a dryer to dry/stop drying the material under test, based on the moisture content value.

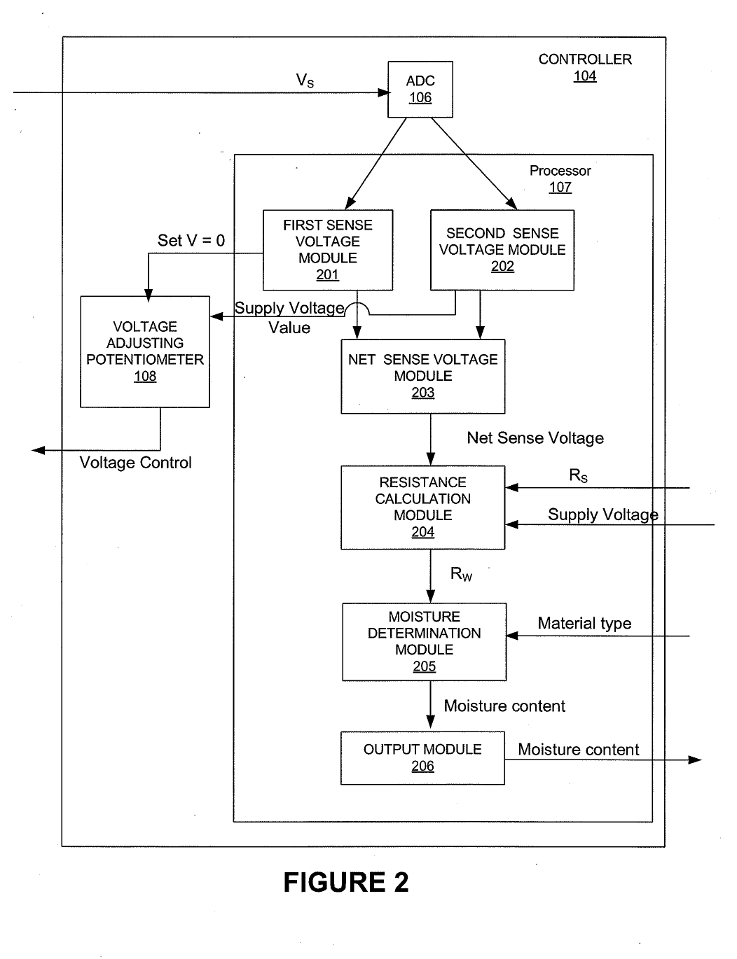

FIG. 2 is a module diagram depicting the internal architecture of controller 104 in more detail, according to one example embodiment. In the example embodiment, the modules shown in FIG. 2 are electronic circuits included in processor 107. In the example embodiment in which the controller is a programmable general purpose personal computer, the modules shown in FIG. 2 are computer-executable process steps that are stored on a computer-readable memory medium executed by the computer.

As shown in FIG. 2, processor 107 includes first sense voltage module 201, second sense voltage module 202, net sense voltage module 203, resistance calculation module 204, moisture determination module 205, and output module 206.

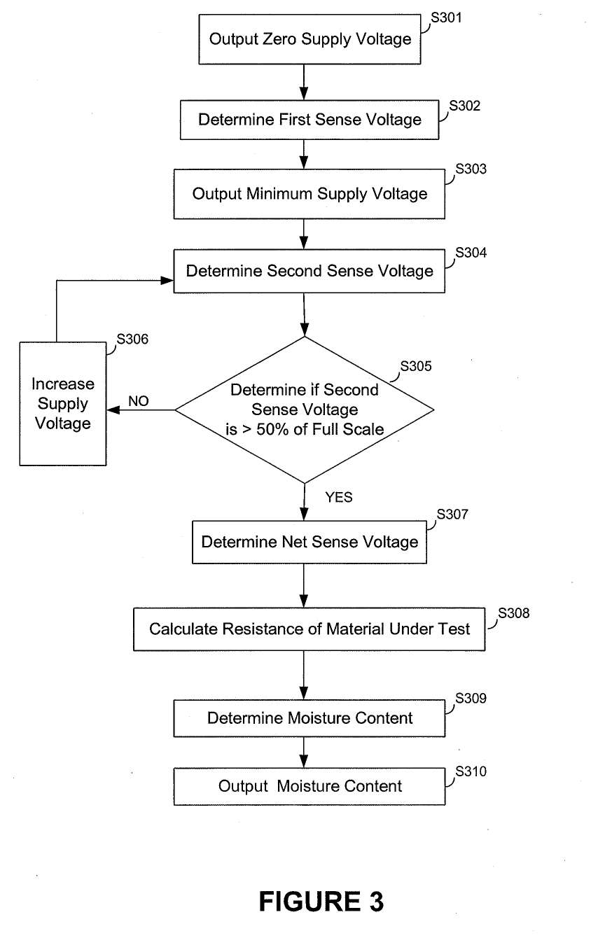

Moisture sensing begins with first sense voltage module 201 providing a zero voltage control signal to voltage adjusting potentiometer 108 (which controls power supply 101 to output a zero supply voltage), as will be described below with respect to FIG. 3. Thereafter, first sense voltage module 201 receives a corresponding digital voltage input applied thereto from ADC 106. The digital input received by first sense voltage module 201 indicates a voltage across sense resistor 103 at a time when the zero supply voltage is applied across sense material under test 102 and sense resistor 103. In response to receiving the digital voltage input from ADC 106, first sense voltage module 201 provides a first sense voltage to net sense voltage module 203.

In response to first sense voltage module 201 providing the first sense voltage to net sense voltage module 203, second sense voltage module 202 provides a non-zero voltage control signal to voltage adjusting potentiometer 108 (which controls power supply 101 to output a non-zero supply voltage, i.e., a voltage that is not the zero supply voltage). Thereafter, second sense voltage module 202 receives a digital voltage input applied thereto from ADC 106. The digital voltage input received by second sense voltage module 202 indicates a voltage across sense resistor 103 at a time when the non-zero supply voltage is applied across sense material under test 102 and sense resistor 103. In response to receiving the digital voltage input from ADC 106, second sense voltage module 202 provides a second sense voltage to net sense voltage module 203.

Net sense voltage module 203 provides a net sense voltage across sense resistor 103 to resistance calculation module 204.

Resistance calculation module 204 receives an input that indicates a resistance value (R_{S}) of sense resistor 103. In an example embodiment, the value R_{S} is read and received from a memory (not shown), however, in other example embodiments, the value R_{S} is received from a user via a user interface. In further example embodiments, the value R_{S} is received from another device via a network interface.

Resistance calculation module 204 also receives an input from power supply 101 that indicates the current value of the supply voltage. Resistance calculation module 204 calculates the resistance (R_{W}) of the material under test (as will be described below with respect to FIG. 3) and provides R_{W} to moisture determination module 205.

Moisture determination module 205 receives R_{W} and a Material Type. Moisture determination module 205 uses the received Material Type and the received resistance R_{W} to determine a moisture content value, as will be described with respect to step S309 of FIG. 3. Moisture determination module 205 provides the determined moisture content value to output module 206, which provides the moisture content value to a device (e.g., a remote device, a display device, or a dryer controller). In an example embodiment, the Material Type is read and received from a memory (not shown), however, in other example embodiments, the Material Type is received from a user via a user interface. In further example embodiments, the Material Type is received from another device via a network interface.

FIG. 3 is a flow diagram for explaining moisture sensing performed by controller 104. At step S301, first sense voltage module 201 provides a zero voltage control signal to voltage adjusting potentiometer 108. In response, voltage adjusting potentiometer 108 provides a zero voltage control signal to power supply 101, which signal controls power supply 101 to provide a zero supply voltage to electrode 105.

At step S302, first sense voltage module 201 receives a digital voltage input from ADC 106, which monitors the analog voltage at electrode 109 (i.e., the voltage across sense resistor 103). First sense voltage module 201 determines a first sense voltage across sense resistor 103 by reading a predetermined number of digital voltage inputs received from ADC 106 at predetermined intervals, and averaging the voltage measurements. In an example embodiment, 18 readings are taken at 1 millisecond intervals, the highest and lowest readings are discarded, and the remaining 16 readings are averaged. This average value is the first sense voltage, which is provided to net sense voltage module 203.

At step S303, second sense voltage module 202 provides a minimum supply voltage value to voltage adjusting potentiometer 108. In response, voltage adjusting potentiometer 108 provides a minimum voltage control signal to power supply 101, which controls power supply 101 to provide a minimum supply voltage to electrode 105. In the example embodiment, the minimum supply voltage is 3 volts.

At step S304, second sense voltage module 202 receives a digital voltage input from ADC 106, which monitors the analog voltage at electrode 109 (i.e., the voltage across sense resistor 103). Second sense voltage module 202 determines a second sense voltage across sense resistor 103 by reading a predetermined number of digital voltage inputs received from ADC 106 at predetermined intervals, and averaging the voltage measurements. In the example embodiment, 18 readings are taken at 1 millisecond intervals, the highest and lowest readings are discarded, and the remaining 16 readings are averaged. This average value is the second sense voltage.

At step S305, second sense voltage module 202 determines whether the second sense voltage is greater than a predetermined percentage of a full-scale voltage measurement. In an example embodiment, the full-scale voltage measurement is 90V, and second sense voltage module 202 determines whether the second sense voltage is greater than 50% of the full-scale voltage measurement (i.e., greater than 45 v), although in other embodiments, other percentages can be used.

In a case where the second sense voltage is not greater than the predetermined percentage of the full-scale voltage measurement (“NO” at Step S305), processing proceeds to step S306. At step S306, second sense voltage module 202 provides voltage adjusting potentiometer 108 with a voltage control signal for increasing the supply voltage. In an example embodiment, second sense voltage module 202 provides voltage adjusting potentiometer 108 with a voltage control signal for doubling the supply voltage (although in other embodiments, other fractions or multiples of the supply voltage can be employed). In response, voltage adjusting potentiometer 108 provides the voltage control signal to power supply 101, which controls power supply 101 to double the supply voltage provided to electrode 105. Thereafter, processing returns to step S304, and the iterative process that includes steps S304, S305, and S306 repeats until the second sense voltage is greater than the predetermined percentage of the full-scale voltage measurement.

In a case where the second sense voltage is greater than the predetermined percentage of the full-scale voltage measurement (“YES” at Step S305), the second sense voltage is provided by second sense voltage module 202 to net sense voltage module 203, and processing proceeds to step S307.

At step S307, net sense voltage module 203 calculates a difference between the second sense voltage and the first sense voltage, and provides the net sense voltage (V_{S}) to resistance calculation module 204.

At step S308, resistance calculation module 204 receives the net sense voltage calculated by net sense voltage module 203. Resistance calculation module 204 also receives an input from power supply 101 that indicates the current value of the supply voltage provided by power supply 101, the supply voltage being the voltage at which the second sense voltage is greater than the predetermined percentage of the full-scale voltage measurement. Additionally, resistance calculation module 204 receives an input that indicates a known resistance value (R_{S}) of sense resistor 103.

Resistance calculation module 204 calculates a resistance of material under test 102 based on the received net sense voltage (V_{S}), the received known resistance value of the sense resistor (R_{S}), and the received supply voltage (V). In particular, resistance calculation module 204 calculates a resistance (R_{W}) of material under test 102 using Ohm's law, as shown in Equation 1:

R_{S}=[(R_{S}/V_{S})*V]−R_{S} (Equation 1)

As shown in Equation 1, R_{W} is the resistance of the material under test, R_{S} is the known resistance of the sense resistor, V_{S} is the received net sense voltage, and V is supply voltage at which the second sense voltage is greater than the predetermined percentage of the full-scale voltage measurement. Resistance calculation module 204 provides the calculated resistance (i.e. R_{W}) to moisture determination module 205, and processing proceeds to step S309.

At step S309, moisture determination module 205 determines a moisture content of the material under test based in part on the calculated resistance of the material under test (R_{W}). In the example embodiment, moisture determination module 205 receives an input that indicates a type of the material under test 102 (e.g., Material Type). Moisture determination module 205 determines a moisture content of the material under test by comparing the calculated resistance value R_{W} with a database that correlates resistance values with moisture content for the received type of the material under test. More specifically, in one example, the moisture determination module 205 uses a database (not shown) to perform a database search using the calculated resistance value and the received Material Type as search keys, and the result of the search is identification of a corresponding moisture content of material 102.

Moisture determination module 205 provides the determined moisture content to output module 206, and processing proceeds to step S310, at which output module 206 outputs the moisture content. In one example embodiment, output module 206 outputs the moisture content to a remote device that is communicatively coupled to controller 104 via a network. Upon receiving the moisture content from output module 206, the remote device performs an action based on the received moisture content. The remote device can be any suitable type of remote device, such as, for example, a server, a base station, a computer, a controller, or the like.

In an example embodiment, the remote device is a display device that displays the moisture content to a user. In another example embodiment, the remote device is a dryer controller that controls a dryer to dry the material under test based on the moisture content. In a case where the moisture content is below a predetermined threshold, the dryer controller controls the dryer to stop drying.

In an example embodiment, the output module is a display device that displays the moisture content to a user. In an example embodiment, the output module is a dryer controller that controls a dryer to drying the material under test based on the moisture content. In a case where the moisture content is below a predetermined threshold, the dryer controller controls the dryer to stop drying.

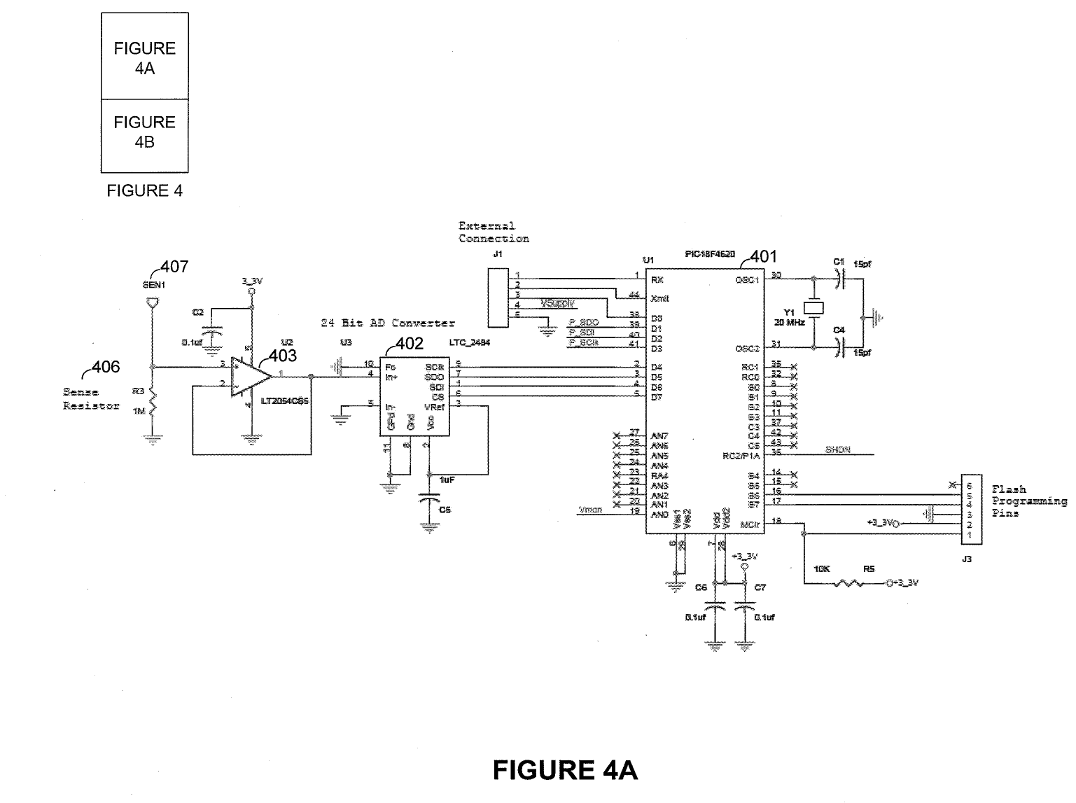

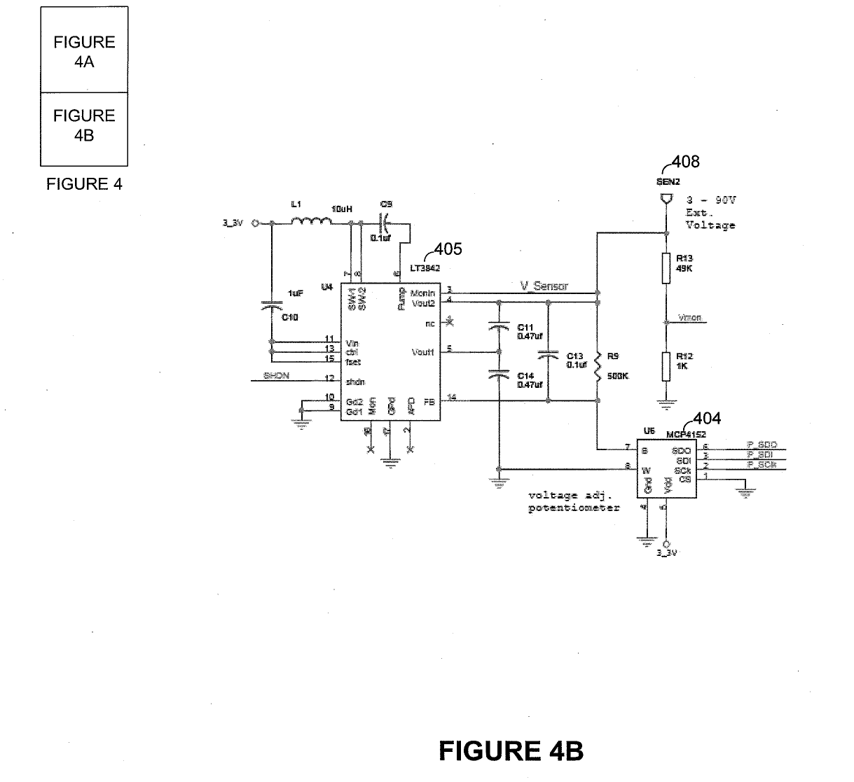

FIG. 4 is a schematic diagram of a moisture sensing device according to an example embodiment. As shown in FIG. 4, the controller includes processor 401, ADC 402, buffer amplifier 403, and voltage adjusting potentiometer 404 (FIG. 4B). Power supply 405 (FIG. 4B) supplies the supply voltage to the material under test via electrode 408, and the controller monitors the voltage across sense resistor 406 at electrode 407. The controller, in one example embodiment, performs functions like the above-described operation of the controller 104 of FIG. 2.

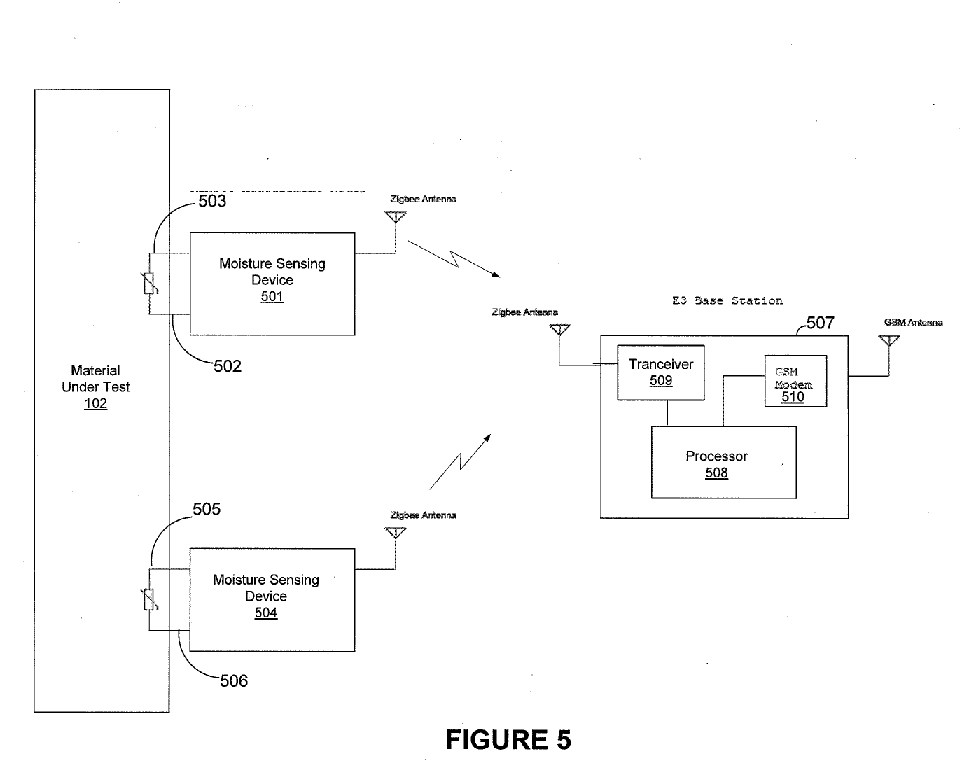

FIG. 5 is block diagram of a moisture measurement system according to an example embodiment. As shown in FIG. 5, moisture sensing devices 501 and 504 are arranged to measure the moisture content at different portions of the same material under test 102. In particular, electrodes 502 and 503 of device 501 are electrically coupled to material 102, and electrodes 505 and 506 of device 504 are electrically coupled to material 102.

In the example embodiment depicted in FIG. 5, the output devices of devices 501 and 504 are ZigBee transceivers based on the IEEE 802.15.4-2003 standard for wireless personal area networks (WPANs). Base station 507 includes processor 508 and GSM modem 510 and ZigBee transceiver 509. Base station 507 receives moisture content from each of devices 501 and 504 via ZigBee transceiver 509. Processor 508 sends the received moisture content to a remote device via a GSM network using GSM modem 510. A device (not shown) receiving the moisture content via the GSM network performs an action based on the received moisture content, such as, for example, displaying the moisture content to a user at a location remote from the location of material under test 102. The output devices of devices 501 and 504, and transceiver 509 are not limited to ZigBee transceivers based on the IEEE 802.15.4-2003 standard for wireless personal area networks (WPANs). In other embodiments, the output devices can be any other suitable type of transceiver, and the transceivers each can be a separate receiver and transmitter, or those components can be integrally formed. In other embodiments, the output devices of devices 501 and 504 can store the moisture content instead of (or in addition to) sending information, and the moisture content can be stored in any of the devices (e.g., 501 and 504).

For example, in the case of determining whether lumber used in a lumber mill is sufficiently dry, a sensing device can be arranged at different portions of a piece of wood to determine moisture content throughout the length of the wood. The moisture content determined by each device is sent to the base station via the ZigBee wireless network, and the base station forwards the received moisture content values to a remote location which processes the received information.

In another example embodiment, moisture sensing devices can be arranged to measure the moisture content of different materials. For example, in the case of a flooded basement, moisture sending devices can be arranged at different portions of the floor and the walls to determine moisture content throughout the room and to determine whether the room is sufficiently dry. The moisture content determined by each device is sent to the base station via the ZigBee wireless network, and the base station forwards the received moisture content values to a remote location which processes the received information.

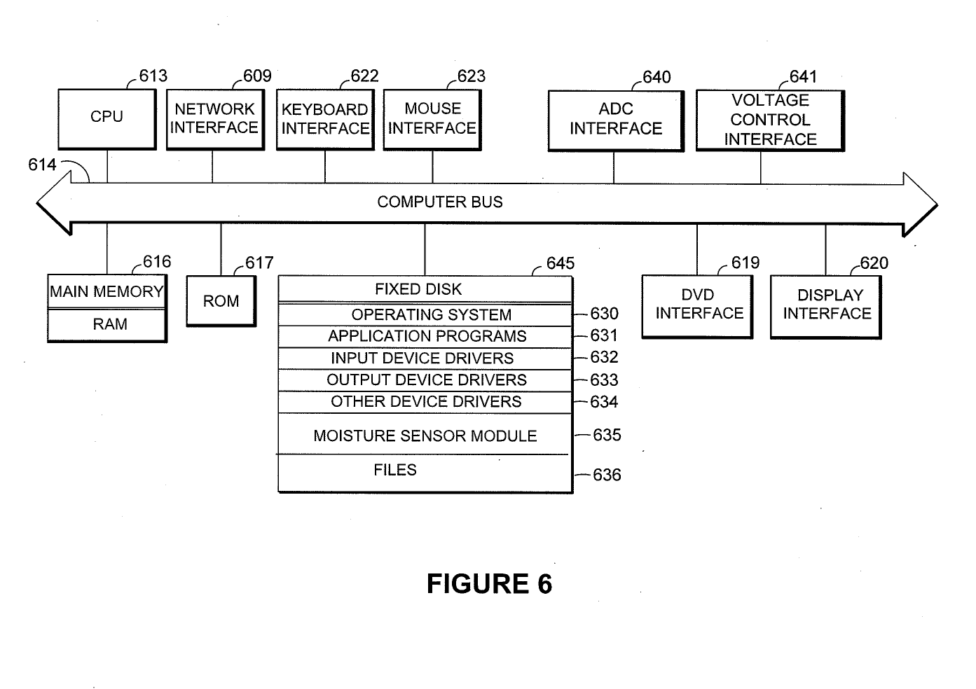

FIG. 6 is a detailed block diagram depicting the internal architecture of a computer according to an example embodiment in which the controller of the moisture sensor device is a programmable general purpose personal computer. In this embodiment, the computer is communicatively coupled to an ADC (not shown) similar to ADC 106 and a voltage adjusting potentiometer (not shown) similar to voltage adjusting potentiometer 108.

As shown in FIG. 6, the computer includes central processing unit (CPU) 613 which interfaces with computer bus 614. Also interfacing with computer bus 614 are fixed disk 645, network interface 609, random access memory (RAM) 616 for use as a main run-time transient memory, read only memory (ROM) 617, DVD disk interface 619, display interface 620 for a monitor (not shown), keyboard interface 622 for a keyboard (not shown), a mouse interface 623 for a pointing device (not shown), ADC interface 640 for an ADC that reads a voltage across a sense resistor, and a voltage control interface 641 for a voltage adjusting potentiometer that controls an adjustable power supply.

RAM 616 interfaces with computer bus 614 so as to provide information stored in RAM 616 to CPU 613 during execution of the instructions in software programs such as an operating system, application programs, moisture sensor modules, and device drivers. More specifically, CPU 613 first loads computer-executable process steps from fixed disk 645, or another storage device into a region of RAM 616. CPU 613 can then execute the stored process steps from RAM 616 in order to execute the loaded computer-executable process steps. Data such as moisture content values, voltage values, resistance values or other information can be stored in RAM 616, so that the data can be accessed by CPU 613 during the execution of computer-executable software programs, to the extent that such software programs have a need to access and/or modify the data.

As also shown in FIG. 6, fixed disk 645 contains computer-executable process steps for operating system 630, and application programs 631, such as word processing programs or moisture sensing programs. Fixed disk 645 also contains computer-executable process steps for device drivers for software interface to devices, such as input device drivers 632, output device drivers 633, and other device drivers 634. Files 638 are available for output to output devices and for manipulation by application programs.

Moisture sensor module 635 comprises computer-executable process steps executed by a computer so as to measure moisture content of a material under test. The computer executable process steps of moisture sensor module 635 include the computer-executable process steps of modules (such as those shown in FIG. 2) that collectively execute instructions for performing a method for measuring moisture content, such as that shown in FIG. 3.

Moisture sensor module 635 generally comprises computer-executable process steps for a process for measuring moisture content of a material under test. Moisture sensor module 635 detects first and second sense voltages across a sense resistor in response to application of respective first and second supply voltages across the sense resistor and the material under test. The material under test is electrically coupled to the sense resistor. Moisture sensor module 635 determines a net sense voltage by determining a difference between the second and first sense voltages. Moisture sensor module 635 determines a resistance of the material under test based on the net sense voltage, a predetermined resistance of the sense resistor, and the second supply voltage. Moisture sensor module 635 determines a moisture content of the material under test based on the resistance of the material under test.

In one example, the computer-executable process steps for moisture sensor module 635 may be configured as a part of operating system 630, as part of an output device driver, or as a stand-alone application program. They may also be configured as a plug-in or dynamic link library (DLL) to the operating system, device driver or application program. For example, moisture sensor module 635 according to example embodiments may be incorporated in an output device driver for execution in a computing device, embedded in the firmware of an output device, or provided in a stand-alone application for use on a general purpose computer. It can be appreciated that the present disclosure is not limited to these embodiments and that the disclosed moisture sensor module may be used in other environments in which moisture sensing is used.

This disclosure has provided a detailed description with respect to particular representative embodiments. It is understood that the scope of the appended claims is not limited to the above-described embodiments and that various changes and modifications may be made without departing from the scope of the claims.

What is claimed is:

1. A method for measuring moisture content of a material under test, the method comprising:
detecting first and second sense voltages across a sense resistor in response to application of respective first and second supply voltages across the sense resistor and the material under test, the material under test being electrically coupled to the sense resistor;
determining a net sense voltage by determining a difference between the second and first sense voltages;
determining a resistance of the material under test based on the net sense voltage, a predetermined resistance of the sense resistor, and the second supply voltage; and
determining a moisture content of the material under test based on the resistance of the material under test.

2. The method of claim 1, wherein the determining of the net sense voltage is performed in response to detecting in said detecting step that the second sense voltage exceeds a predetermined percentage of a full-scale voltage measurement of a controller that controls an adjustable power supply to increase the second supply voltage until the second sense voltage exceeds the predetermined percentage of the full-scale voltage measurement.

3. The method of claim 1, wherein the resistance of the material under test is determined using Ohm's law.

4. The method of claim 1, further comprising outputting the moisture content by way of a user-perceptible output interface.

5. The method of claim 1, further comprising outputting the moisture content to a dryer controller that controls a dryer to stop drying the material under test based on the moisture content.

6. The method of claim 1, further comprising outputting the moisture content to a remote device via a network.

7. The method of claim 2, wherein the predetermined percentage of the full-scale voltage measurement of the controller is fifty percent (50%), and the controller controls the adjustable power supply to double the second supply voltage until the second sense voltage is greater than half of the full-scale voltage measurement.

8. The method of claim 1, wherein each of the first sense voltage and the second sense voltage is detected by taking a predetermined number of voltage measurements of the sense resistor at predetermined intervals, and averaging the voltage measurements.

9. The method of claim 2, wherein the adjustable power supply is an adjustable DC-DC converter.

10. The method of claim 2, wherein the controller includes an analog-to-digital-converter (ADC), a processor, and a voltage adjusting potentiometer, wherein the ADC monitors the voltage across the sense resistor and the processor reads an output of the ADC to detect the first sense voltage and the second sense voltage, and wherein the processor uses the voltage adjusting potentiometer to control the adjustable power supply.

11. The method of claim 10, wherein the analog-to-digital converter (ADC) is a 24-bit delta-sigma ADC that includes a buffer amplifier.

12. A moisture sensor device for measuring moisture content of a material under test, the device comprising:
an analog-to-digital-converter (ADC);
a voltage adjusting potentiometer; and
a processor constructed to:
use the voltage adjusting potentiometer to apply respective first and second supply voltages across a sense resistor and the material under test
use the ADC to detect first and second sense voltages across the sense resistor in response to application of the respective first and second supply voltages across the sense resistor and the material under test, the material under test being electrically coupled to the sense resistor;
determine a net sense voltage by determining a difference between the second and first sense voltages;
determine a resistance of the material under test based on the net sense voltage, a predetermined resistance of the sense resistor, and the second supply voltage; and
determine a moisture content of the material under test based on the resistance of the material under test.

13. The device of claim 12, wherein the ADC, the voltage adjusting potentiometer, and the processor are included in a controller.

14. The device of claim 12, wherein the processor determines the net sense voltage in response to detecting that the second sense voltage exceeds a predetermined percentage of a full-scale voltage measurement of the ADC, and wherein the processor uses the voltage adjusting potentiometer to control an adjustable power supply to increase the second supply voltage until the second sense voltage exceeds the predetermined percentage of the full-scale voltage measurement.

15. The device of claim 12, wherein the processor outputs the moisture content by way of a user-perceptible output interface.

16. The device of claim 12, wherein the processor outputs the moisture content to a dryer controller that controls a dryer to stop drying the material under test based on the moisture content.

17. The device of claim 12, wherein the processor outputs the moisture content to a remote device via a network.

18. The device of claim 14, wherein the predetermined percentage of the full-scale voltage measurement of the controller is fifty percent (50%), and the processor controls the adjustable power supply to double the second supply voltage until the second sense voltage is greater than half of the full-scale voltage measurement.

19. The device of claim 1, wherein each of the first sense voltage and the second sense voltage is detected by taking a predetermined number of voltage measurements of the sense resistor at predetermined intervals, and averaging the voltage measurements.

20. A computer-readable memory medium on which is stored computer-executable process steps for causing a computer to measure moisture content of a material under test, said process steps comprising:
detecting first and second sense voltages across a sense resistor in response to application of respective first and second supply voltages across the sense resistor and the material under test, the material under test being electrically coupled to the sense resistor;
determining a net sense voltage by determining a difference between the second and first sense voltages;
determining a resistance of the material under test based on the net sense voltage, a predetermined resistance of the sense resistor, and the second supply voltage; and
determining a moisture content of the material under test based on the resistance of the material under test.
